(19) United States
(12) Patent Application Publication
(10) Pub. No.: US 2006/0214258 A1
(43) Pub. Date: Sep. 28, 2006

(54) Semiconductor device and fabrication method of the same

(76) Inventor: Masahiro Kiyotoshi, Sagamihara-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/133,359

(22) Filed: May 20, 2005

(30) Foreign Application Priority Data
Mar. 24, 2005 (JP) 2005-086342

(51) Int. Cl. H01L 29/00

(52) U.S. Cl. 257/510

(57) ABSTRACT

A semiconductor device includes a first element isolation trench formed in a semiconductor substrate and having an STI (Shallow Trench Isolation) structure, a first insulating film formed in the first element isolation trench and mainly containing a metal oxide, and a polysilazane film formed on the first insulating film and filled in the first element isolation trench.

### CROSS-REFERENCE TO RELATED APPLICATIONS

This application is based upon and claims the benefit of priority from prior Japanese Patent Application No. 2005-086342, filed Mar. 24, 2005, the entire contents of which are incorporated herein by reference.

### BACKGROUND OF THE INVENTION

1. Field of the Invention

The present invention relates to a semiconductor device using STI (Shallow Trench Isolation), and a fabrication method of the same.

2. Description of the Related Art

To improve the performance (to increase the operating speed and reduce the power consumption) of elements of LSI by higher integration density, downsizing of LSI's minimum design rule advances to below 90 nm even on the mass-production level. Although the technical difficulties are increasing, the LSI downsizing is expected to further progress to sub-50 nm in the future.

In the stage of development, a downsized logic device in which the gate length is decreased to about 10 nm is fabricated by way of trial. To downsize an element, it is important to downsize an element isolation region which occupies more than half the element area. Recently, as an element isolation region formation method, an STI (Shallow Trench Isolation) technique suited to downsizing is used. In this STI technique, an element isolation region is formed by burying an insulating film in a trench formed by anisotropic etching. By downsizing of an element, the trench width of this element isolation region is about 90 nm to 70 nm, i.e., has reached a trench width of 0.1 μm or less. Also, in memories in which high integration is regarded as important, the active area width and element isolation region width of a transistor and the like are about 90 nm to 70 nm, i.e., almost reach the region of 0.1 μm or less. Therefore, downsizing of an element isolation region is also becoming important.

Downsizing increases the difficulties in the formation of an element isolation region for the reason explained below. That is, isolation between elements is determined by the effective distance between adjacent elements, i.e., the shortest distance when a circuit is made around an element isolation region. To maintain the insulating properties even when a device is downsized, it is necessary to hold the conventional effective distance, i.e., to hold the depth of a trench of STI substantially constant or make the trench deeper. Since the width of the trench of STI decreases by downsizing, the aspect ratio of a trench in which an insulating film is filled increases for each generation of downsizing. This makes STI filling very difficult.

The filling technique using a silicon oxide film formed by HDP-CVD (High Density Plasma enhanced Chemical Vapor Deposition) is presently used as a standard STI insulating film fill technique. However, in STI fill of a generation of 0.1 μm or less, the aspect ratio becomes more than 3. This makes it very difficult to perform fill without producing any voids (unfilled portions).

Note that examples of prior art reference information related to the invention of this application are U.S. Pat. Nos. 6,429,136, 6,479,369, and 6,699,799.

### BRIEF SUMMARY OF THE INVENTION

A semiconductor device according to a first aspect of the present invention comprises a first element isolation trench formed in a semiconductor substrate and having an STI (Shallow Trench Isolation) structure, a first insulating film formed in the first element isolation trench and mainly containing metal oxide, and a polysilazane film formed on the first insulating film and filled in the first element isolation trench.

A semiconductor device according to a second aspect of the present invention comprises a first element isolation trench formed in a semiconductor substrate and having an STI structure, a first HSQ film formed in the first element isolation trench, and a polysilazane film formed on the first HSQ film and filled in the first element isolation trench.

A semiconductor device manufacturing method according to a third aspect of the present invention comprises forming a first element isolation trench having an STI structure in a semiconductor substrate, forming a first insulating film mainly containing a metal oxide in the first element isolation trench, forming a polysilazane film on the first insulating film, and forming a first STI region by planarizing the first insulating film and polysilazane film.

A semiconductor device manufacturing method according to a fourth aspect of the present invention comprises forming a first element isolation trench having an STI structure in a semiconductor substrate, forming a first HSQ film in the first element isolation trench, forming a polysilazane film on the first HSQ film, and forming a first STI region by planarizing the first HSQ film and polysilazane film.

### BRIEF DESCRIPTION OF THE SEVERAL VIEWS OF THE DRAWING

FIG. 1A is a sectional view showing a semiconductor device according to the first embodiment of the present invention;

FIG. 1B is an enlarged schematic view of an STI region shown in FIG. 1A;

FIGS. 2 to 5 are sectional views showing the fabrication steps of the semiconductor device according to the first embodiment of the present invention;

FIG. 6 is a view showing the results of evaluation of off-leakage currents in the first embodiment of the present invention and in a comparative example;

FIG. 7A is a sectional view showing a semiconductor device according to the second embodiment of the present invention;

FIG. 7B is an enlarged schematic view of an STI region shown in FIG. 7A;

FIGS. 8 to 11 are sectional views showing the fabrication steps of the semiconductor device according to the second embodiment of the present invention;

FIG. 12 is a view showing the results of evaluation of N-well-to-N-well junction-leakage currents in the second embodiment of the present invention and in a comparative example;

FIG. 13 is a sectional view showing the semiconductor device according to the comparative example shown in FIG. 12;

FIG. 14 is a sectional view showing a semiconductor device according to the third embodiment of the present invention;

FIGS. 15 to 18 are sectional views showing the fabrication steps of the semiconductor device according to the third embodiment of the present invention;

FIG. 19 is a sectional view showing a nonvolatile semiconductor device according to the fourth embodiment of the present invention; and

FIGS. 20A and 20B are graphs showing the Id-Vg characteristics of a plurality of MOS transistors different in channel width.

### DETAILED DESCRIPTION OF THE INVENTION

As described above, it is conventionally difficult to downsize STI (Shallow Trench Isolation) because it is difficult to fill an insulating film in a very narrow STI trench of STI.

To avoid this problem of filling of the STI trench, it is being attempted to use a spin-coating film such as an SOG (Spin On Glass) film. When this SOG film is used, an SOG chemical can reflow into the STI trench after spin-coating, so the SOG film can be easily filled even in a very high-aspect-ratio STI trench. In addition, since the SOG fill is less dependent on an underlying layer, the film is effective to realize complete STI fill without voids (unfilled portions) or seams (seamed unfilled portions). Accordingly, the SOG film is being extensively studied as a candidate for STI trench fill in recent years.

In particular, a polysilazane (perhydrosilazane polymer [(—SiH₂NH—)ₙ]) film is recently attracting a great deal of attention as a promising STI fill material. This is so because the polysilazane film has the following advantages. That is, the polysilazane film is an inorganic material so that it should not contain organic impurities, and causes a small film shrinkage as about 10%, which is relatively small in comparison with a normal SOG film, by the polysilazane reaction mechanism which forms a silicon oxide film by oxidizing Si—N bonds. This allows coating of a thick polysilazane film about 1 μm thick.

When, however, the present inventors actually used the polysilazane film as a material for STI trench fill, the following problems arose.

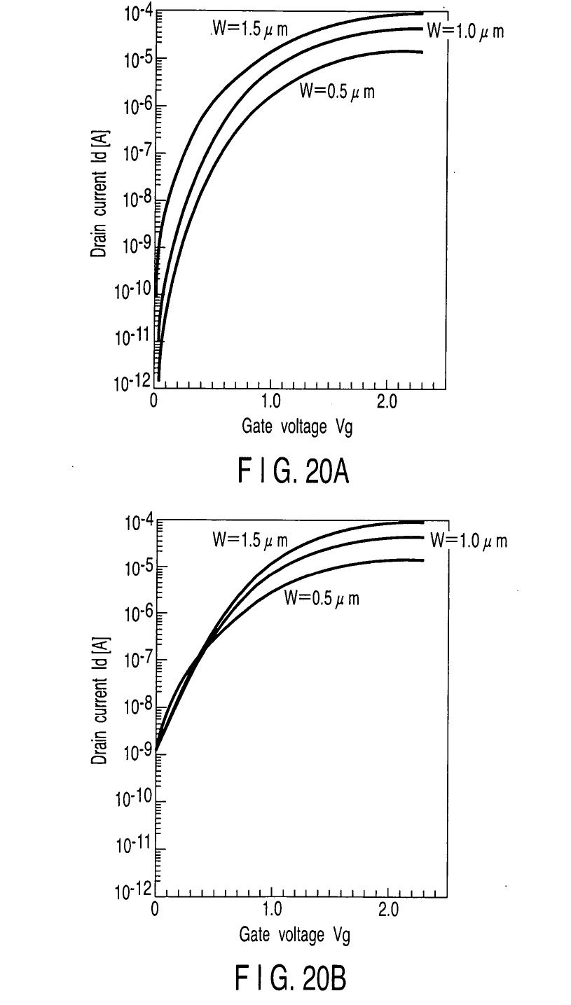

FIGS. 20A and 20B are graphs showing the Id-Vg characteristics of a plurality of MOS transistors different in channel width. FIG. 20A shows the results when a silicon oxide film (HDP-CVD silicon oxide film) formed by HDP-CVD (High Density Plasma-Chemical Vapor Deposition) is filled in an STI trench. FIG. 20B shows the results when a polysilazane film is filled in an STI trench.

As shown in FIG. 20A, in the Id-Vg characteristics of the HDP-CVD silicon oxide film, a drain current Id depends on a channel width W, and reduces at a threshold voltage Vth or less.

By contrast, as shown in FIG. 20B, the Id-Vg characteristics of the polysilazane film are as follows. When a gate voltage Vg is high, similar to FIG. 20A, the drain current Id depends on the channel width W. However, if the gate voltage Vg is low, unlike in FIG. 20A, the drain current Id does not reduce. In addition, the drain current Id having a predetermined value flows regardless of the channel width W. That is, an off-leakage current Ioff independent of the channel width W increases.

As described above, in the polysilazane film, the off-leakage current Ioff increases independently of the channel width W because the threshold voltage Vth in the end portion of the channel lowers. When evaluation was actually performed by SIMS (Secondary Ion Mass Spectroscopy), 1×10²¹ cm⁻³ of C (carbon) remained as an impurity in the polysilazane film after coating, and 1×10²⁰ cm⁻³ of C remained as an impurity even after steam oxidation was performed. That is, polysilazane itself is an inorganic material and hence does not contain any carbon. Therefore, a carbon component of an organic solvent in a coating liquid chemical presumably remained as a positive fixed electric charge in the polysilazane film even after coating→baking, and this probably increased the off-leakage current Ioff of the MOS transistor.

As described above, when the polysilazane film is used as a material to be filled in an STI trench, C resulting from a solvent in a polysilazane solution remains as a positive fixed electric charge in the polysilazane film even after a heat-treatment, and this lowers the threshold voltage Vth and increases the off-leakage current Ioff.

To make downsizing of STI feasible, therefore, the present invention provides a semiconductor device which uses, as a filling material, a polysilazane film capable of being filled in a narrow STI trench, and which can also avoid the above-mentioned problems (e.g., the increase in off-leakage current caused by fixed electric charge) found by the present inventors, which arise when the polysilazane film is used, and provides a method of fabricating the semiconductor device.

Embodiments of the present invention as described above will be explained below with reference to the accompanying drawing.

### First Embodiment

The first embodiment is an example in which a hafnia [HfO₂] film is formed as a liner film (undercoat) of a polysilazane film in an STI trench.

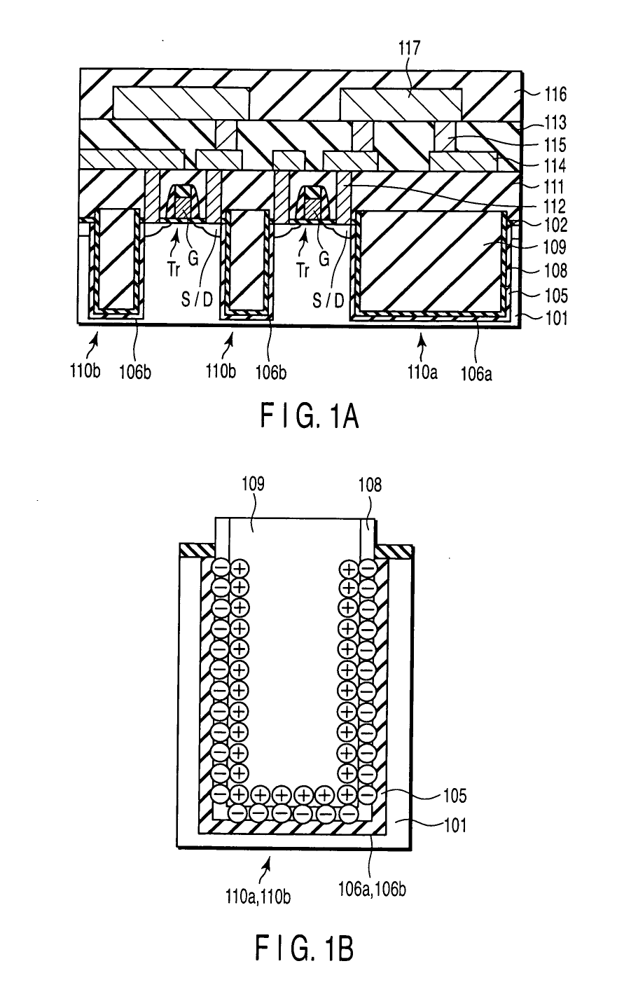

FIG. 1A is a sectional view of a semiconductor device according to the first embodiment of the present invention. FIG. 1B is a schematic enlarged view of an STI region shown in FIG. 1A. This semiconductor device according to the first embodiment will be explained below.

As shown in FIG. 1A, element isolation trenches 106a and 106b having an STI structure are formed in a semiconductor substrate 101, and a polysilazane film 109 is filled in the element isolation trenches 106a and 106b. As an undercoat of the polysilazane film 109, a hafnia film 108 is formed in the element isolation trenches 106a and 106b. In addition, a silicon thermal oxide film 105 is formed below the hafnia film 108. In this manner, STI regions 110a and 110b are formed. The STI region 110a functions as, e.g., a region which isolates a memory cell array portion and peripheral circuit portion, or a region which isolates the memory cell array portion and a logic portion. The STI regions 110b function as, e.g., regions which isolate elements in the memory cell array portion. Therefore, the width of the element isolation trench 106a is larger than that of the element isolation trenches 106b.

In element regions isolated by the STI regions 110a and 110b, transistors Tr each having a gate electrode G and source/drain diffusion layers S/D are formed. Metal interconnections 114 are connected to the source/drain diffusion layers S/D via contact plugs 112, and metal interconnections 117 are connected to the metal interconnections 114 via contact plugs 115.

As shown in FIG. 1B, in the element isolation trenches 106a and 106b, the hafnia film 108 is formed below the polysilazane film 109. In accordance with the properties of the materials, the polysilazane film 109 has positive fixed electric charge, and the hafnia film 108 has negative fixed electric charge instead of positive fixed electric charge. Therefore, the positive fixed electric charge resulting from the polysilazane film 109 is canceled by the negative fixed electric charge resulting from the hafnia film 108. Accordingly, the hafnia film 108 desirably has a film thickness by which the positive fixed electric charge due to the polysilazane film 109 can be canceled. The hafnia film 108 may also be partially formed in the interface between the polysilazane film 109 and silicon thermal oxide film 105 depending on a process. However, to increase the electric charge canceling effect, the hafnia film 108 is desirably formed in the whole of this interface.

A liner film of the polysilazane film 109 is not limited to the hafnia film 108, but can be any insulating film mainly containing a metal oxide having negative fixed electric charge which cancels the influence of the positive fixed electric charge of the polysilazane film 109. Examples of the insulating film mainly containing this metal oxide are metal oxides, metal oxynitrides, metal silicates, and metal silicon oxynitrides. Each of the metal oxides, metal oxynitrides, metal silicates, and metal silicon oxynitrides contains at least one of aluminum, hafnium, zirconium, plesiodium, lanthanum, holonium, and erbium as a metal element. It is readily possible to evenly form a thin film of any of these materials in the high-aspect-ratio element isolation trenches 106a and 106b.

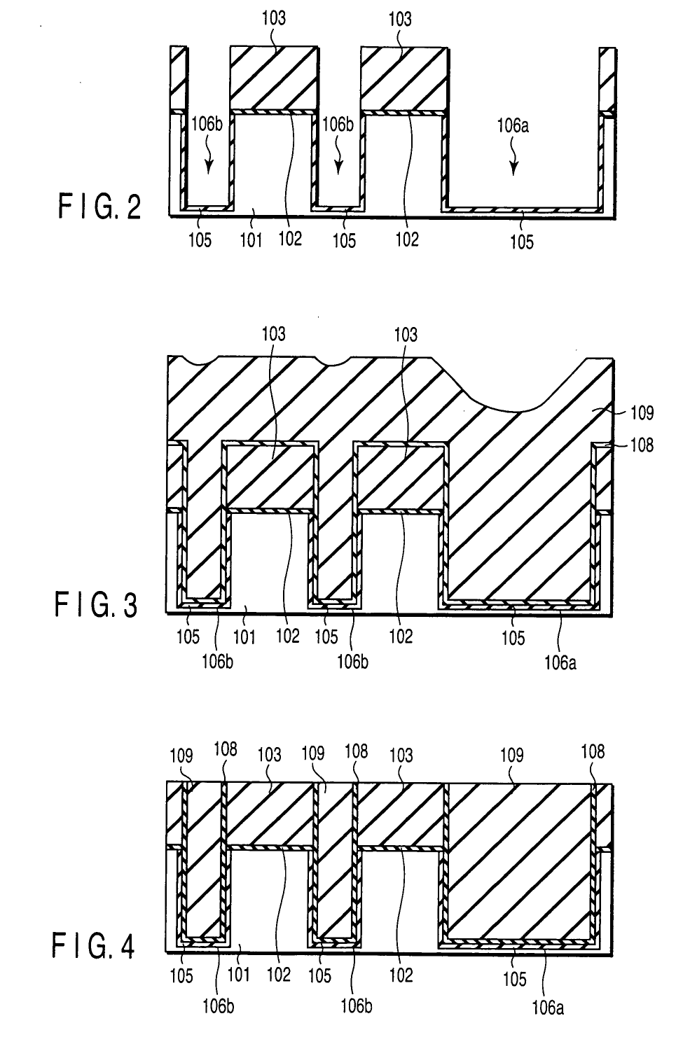

FIGS. 2 to 5 are sectional views showing the fabrication steps of the semiconductor device according to the first embodiment of the present invention. The fabrication method of the semiconductor device according to the first embodiment will be explained below.

First, as shown in FIG. 2, a silicon thermal oxide film 102 having a film thickness of, e.g., 5 nm is formed on a semiconductor substrate (e.g., a silicon substrate) 101, and a silicon nitride film 103 serving as a polishing stopper of CMP (Chemical Mechanical Polish) and having a film thickness of, e.g., 180 nm is formed. Then, a CVD silicon oxide film (not shown) serving as a mask of RIE (Reactive Ion Etching) is formed on the silicon nitride film 103 and coated with a photoresist (not shown). The photoresist is processed by the conventional photolithography technique. This photoresist is used as a mask to process the CVD silicon oxide film by RIE, thereby forming a hard mask (not shown). After that, the photoresist is removed by etching using an asher and a solution mixture of sulfuric acid and aqueous hydrogen peroxide. The hard mask made of the CVD silicon oxide film is used to sequentially process the silicon nitride film 103, silicon thermal oxide film 102, and semiconductor substrate 101 by RIE, thereby forming trenches having an etching depth of, e.g., 300 nm in the semiconductor substrate 101. Subsequently, the CVD silicon oxide film is removed by hydrofluoric acid steam. The inner surfaces of the trenches are then thermally oxidized to form a silicon thermal oxide film 105 having a film thickness of, e.g., 3 nm on the side surfaces and bottom surfaces of the trenches. In this manner, element isolation trenches 106a and 106b having an STI structure are formed.

As shown in FIG. 3, a hafnia film 108 having a film thickness of, e.g., 5 nm is formed in the element isolation trenches 106a and 106b and on the silicon nitride film 103 by LPCVD (Low Pressure Chemical Vapor Deposition). The film formation conditions of the hafnia film 108 formed by LPCVD are that hafnium tetra tertiary butoxide [HTB: [Hf(OC₄H₉)₄]] and oxygen are used as source gases, and the film formation temperature is 300° C. Note that the hafnia film 108 may also be formed by ALD (Atomic Layer Deposition).

Then, a polysilazane film 109 having a film thickness of, e.g., 650 nm is formed on the hafnia film 108 by spin coating. A practical formation method of the polysilazane film 109 is as follows.

(a) First, a perhydrosilazane polymer [(SiH₂NH)ₙ] solution is prepared by dispersing a perhydrosilazane polymer in, e.g., xylene or dibutylether.

(b) Then, the hafnia film 108 is coated with this perhydrosilazane polymer solution by spin coating. Since this step is liquid coating, the perhydrosilazane polymer is filled even in the high-aspect-ratio element isolation trenches 106a and 106b without producing any voids or seams. The spin coating conditions are that the rotational speed of the semiconductor substrate 101 is 1,000 rpm, the rotation time is 30 sec, the dropping amount of the perhydrosilazane polymer solution is 2 cc, and the target coating film thickness is 600 nm.

(c) An appropriate heat-treatment is then performed to change the film of the perhydrosilazane polymer solution into a polysilazane film 109 of a silicon oxide film containing about 0.1% of nitrogen. In this heat-treatment, the semiconductor substrate 101 on which the film is formed is first heated to 150° C. on a hotplate, and then baked in an inert gas ambient for 3 min, thereby volatilizing the solvent in the perhydrosilazane polymer solution. In this state, a few % to around ten % of the carbon or hydrocarbon resulting from the solvent remains as an impurity in the film.

After being formed by steps (a) to (c) described above, the polysilazane film 109 is heat-treated in a steam ambient at 350° C. to 450° C., thereby removing the impurity carbon or hydrocarbon in the film, and converting most of Si—N bonds in the film into Si—O bonds. This reaction typically progresses as indicated by
SiH₂NH+20→SiO₂+NH₃ (1)

In addition, a heat-treatment is performed in a furnace at 900° C. for 60 min. The polysilazane film 109 is densified by this heat-treatment. Since, however, the impurity carbon in the film cannot be completely removed, a fixed electric charge of about 1×10¹²/cm² remains in the polysilazane film 109.

As shown in FIG. 4, the polysilazane film 109 and hafnia film 108 are polished by CMP by using the silicon nitride film 103 as a stopper. As a consequence, the polysilazane film 109 and hafnia film 108 remain only in the element isolation trenches 106a and 106b.

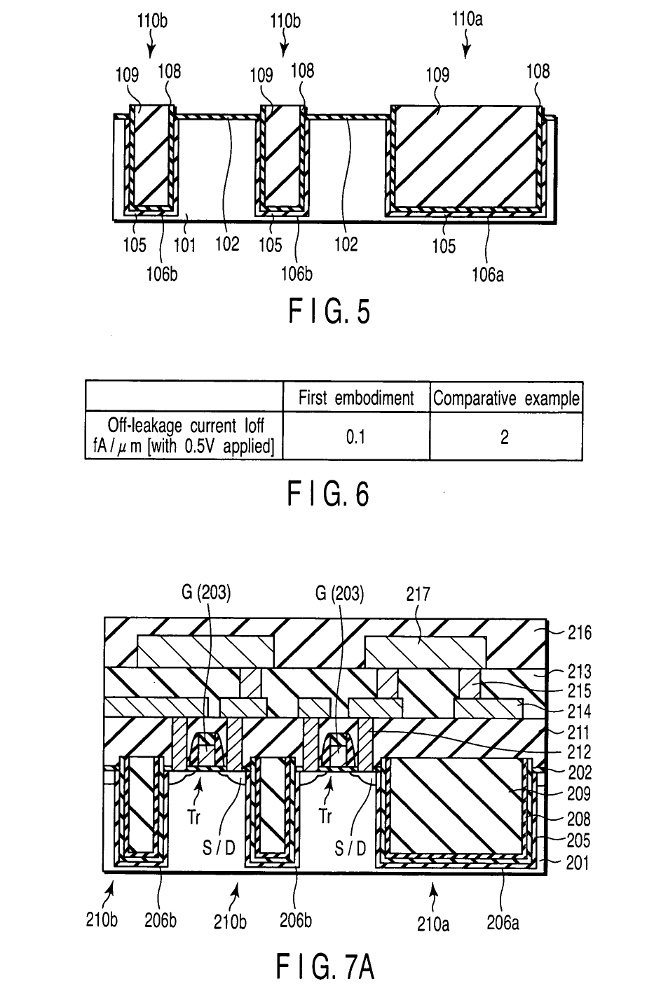

As shown in FIG. 5, the polysilazane film 109 is etched back to a desired height by wet etching. After that, the silicon nitride film 103 and hafnia film 108 are partially removed in hot phosphoric acid to form STI regions 110a and 110b.

Then, as shown in FIG. 1A, a silicon thermal oxide film serving as a gate oxide film is formed, gate electrodes G are formed on this silicon thermal oxide film, and source/drain diffusion layers S/D are formed in the semiconductor substrate 101 on the two sides of each gate electrode G. In this way, transistors Tr are completed. After that, the conventional techniques are used to form contact plugs 112 in a PMD (Pre-Metal Dielectric) 111, form metal interconnections 114 and contact plugs 115 in an ILD (Inter-Layer Dielectric) 113, and form metal interconnections 117 in an ILD 116. In this manner, a semiconductor device is completed.

In the first embodiment described above, the polysilazane film 109 is used as a material to be filled in the element isolation trenches 106a and 106b. Since the polysilazane film 109 is a coating film having good filling properties, it can be easily filled even in the high-aspect-ratio, downsized element isolation trenches 106a and 106b. In addition, the polysilazane film 109 has the advantage that it hardly peels off even when its film thickness is large. Accordingly, when the polysilazane film 109 is used as a material to be filled in the element isolation trenches 106a and 106b, it is possible to avoid the problem of filling properties caused by downsizing of the element isolation trenches 106a and 106b.

Also, as described previously, when the polysilazane film 109 is in direct contact with a silicon substrate or is close to it via an insulating film, positive fixed electric charge resulting from impurity carbon appears. This deteriorates the performance due to, e.g., a shift of the threshold voltage Vth of the transistor Tr, an increase in off-leakage current Ioff, and a decrease in mobility. In this embodiment, however, the hafnia film 108 is formed between the polysilazane film 109 and semiconductor substrate 101 (silicon thermal oxide film 105). Therefore, the positive fixed electric charge resulting from the polysilazane film 109 can be canceled by negative fixed electric charge resulting from the hafnia film 108. This makes it possible to suppress the above-mentioned electrical adverse effects of the polysilazane film 109.

For example, FIG. 6 shows the results of evaluation of off-leakage currents in the first embodiment of the present invention and in a comparative example. In this comparative example, a polysilazane film alone is filled in STI trenches. As shown in FIG. 6, the off-leakage current Ioff of this embodiment is much lower than that of the comparative example. This indicates that the increase in off-leakage current can be suppressed.

In the first embodiment of the present invention as described above, the very narrow STI regions 110a and 110b of 50 nm or less can be formed while the electrical adverse effects, such as the increase in off-leakage current Ioff, of the polysilazane film 109 are suppressed. Consequently, the performance of the semiconductor device can be further improved by downsizing.

### Second Embodiment

In the above first embodiment, the gate electrode G is formed after the STI regions 110a and 110b are formed. In the second embodiment, however, a material layer serving as a gate oxide film and gate electrode is preformed on a semiconductor substrate before STI regions are formed.

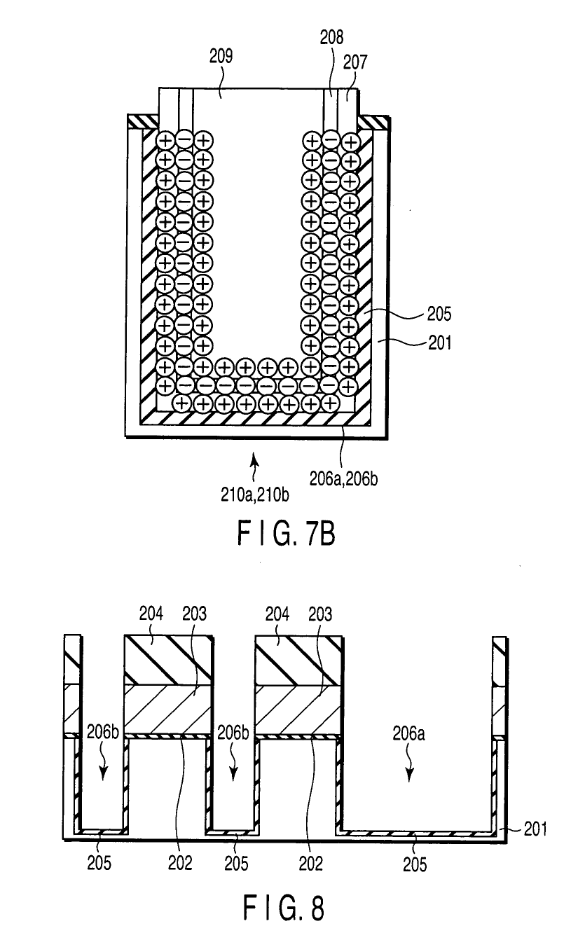

FIG. 7A is a sectional view of a semiconductor device according to the second embodiment of the present invention. FIG. 7B is a schematic enlarged view of an STI region shown in FIG. 7A. This semiconductor device according to the second embodiment will be described below.

As shown in FIGS. 7A and 7B, the second embodiment differs from the first embodiment in that a polysilicon film 203 serving as a gate oxide film 202 and gate electrode G is formed on a semiconductor substrate 201 before STI regions 210a and 210b are formed. When the gate electrode G is thus preformed, it is possible to suppress, e.g., field concentration to the edge portions of the gate electrode G. On the other hand, in a thermal treatment step for forming the STI regions 210a and 210b, the gate oxide film 202 thermally deteriorates, or bird's beaks form in the edge portions of the gate oxide film 202.

In the second embodiment, therefore, a silicon nitride film 207 is formed on the inner surfaces of STI trenches 206a and 206b before a polysilazane film 209 is filled, thereby protecting the gate oxide film 202 against the problems described above. In addition, to cancel positive fixed electric charge of the silicon nitride film 207 and polysilazane film 209, an alumina [Al₂O₃] film 208 is formed between the silicon nitride film 207 and polysilazane film 209.

The alumina film 208 desirably has a film thickness by which the positive fixed electric charge resulting from the polysilazane film 209 and the positive fixed electric charge resulting from the silicon nitride film 207 can be canceled. The alumina film 208 may also be partially formed in the interface between the polysilazane film 209 and silicon nitride film 207 depending on a process. However, to increase the electric charge canceling effect, the alumina film 208 is desirably formed over the whole of this interface.

An insulating film formed between the silicon nitride film 207 and polysilazane film 209 is not limited to the alumina film 208, but can be any insulating film mainly containing a metal oxide having a negative fixed electric charge which cancels the influence of the positive fixed electric charge, as described in the first embodiment.

Also, an insulating film for protecting the gate oxide film 202 is not limited to the silicon nitride film 207. For example, it is also possible to use an HTO film (High Temperature Oxide: a silicon oxide film formed by CVD using SiH₂Cl₂ and N₂O).

FIGS. 8 to 11 are sectional views showing the fabrication steps of the semiconductor device according to the second embodiment of the present invention. The fabrication method of the semiconductor device according to the second embodiment will be explained below.

First, as shown in FIG. 8, a gate oxide film 202 is formed on a semiconductor substrate (e.g., a silicon substrate) 201, and a polysilicon film 203 serving as a gate electrodes G and having a film thickness of, e.g., 150 nm is formed on the gate oxide film 202. In addition, a silicon nitride film 204 serving as a polishing stopper of CMP and having a film thickness of, e.g., 100 nm is formed. Then, a CVD silicon oxide film (not shown) serving as a mask of RIE is formed on the silicon nitride film 204 and coated with a photoresist (not shown). The photoresist is processed by the conventional photolithography technique. This photoresist is used as a mask to process the CVD silicon oxide film by RIE, thereby forming a hard mask (not shown). After that, the photoresist is removed by etching using an asher and a solution mixture of sulfuric acid and aqueous hydrogen peroxide. The hard mask made of the CVD silicon oxide film is used to sequentially process the silicon nitride film 204, polysilicon film 203, gate oxide film 202, and semiconductor substrate 201 by RIE, thereby forming trenches having an etching depth of, e.g., 200 nm in the semiconductor substrate 201. Subsequently, the CVD silicon oxide film is removed by hydrofluoric acid steam. The inner surfaces of the trenches are then thermally oxidized to form a silicon thermal oxide film 205 having a film thickness of, e.g., 4 nm on the side surfaces and bottom surfaces of the trenches. In this manner, element isolation trenches 206a and 206b having an STI structure are formed.

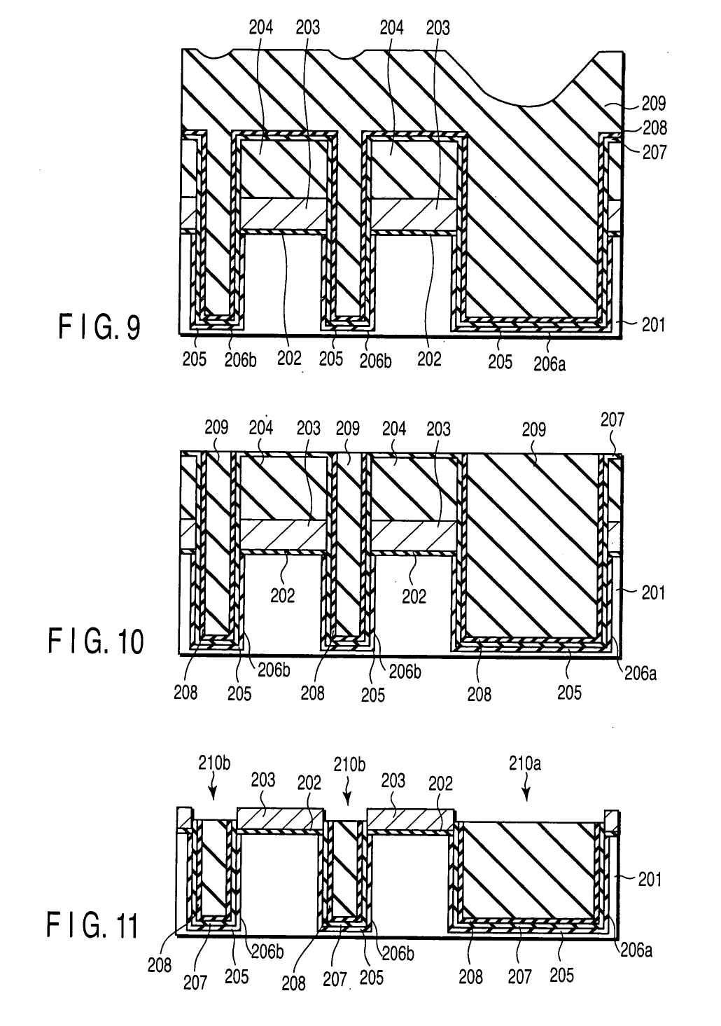

As shown in FIG. 9, a silicon nitride film 207 having a film thickness of, e.g., 5 nm is formed in the element isolation trenches 206a and 206b and on the silicon nitride film 204 by LPCVD. Note that the silicon nitride film 207 may also be formed by ALD.

An alumina film 208 having a film thickness of, e.g., 10 nm is formed on the silicon nitride film 207 by ALD. The ALD film formation conditions of the alumina film 208 are that trimethyl aluminum [TMA: [Al(CH₃)₃]] and O₃ are used as source gases, the film formation temperature is 260° C., and TMA and O₃ are alternately supplied at a cycle of 10 sec. Note that the alumina film 208 may also be formed by LPCVD.

Then, a polysilazane film 209 having a film thickness of, e.g., 600 nm is formed on the alumina film 208 by spin coating. Coating and baking of the polysilazane film 209 are the same as in the first embodiment, so an explanation thereof will be omitted.

The polysilazane film 209 is then heat-treated in a steam ambient at 800° C., thereby removing impurity carbon or hydrocarbon in the film, and converting most of the Si—N bonds in the film into Si—O bonds.

As shown in FIG. 10, the polysilazane film 209 and alumina film 208 are polished by CMP by using the silicon nitride film 207 as a stopper. As a consequence, the polysilazane film 209 and alumina film 208 remain only in the element isolation trenches 206a and 206b.

As shown in FIG. 11, the polysilazane film 209 is etched back to a desired height by wet etching. After that, the silicon nitride films 204 and 207 are partially removed in hot phosphoric acid to form STI regions 210a and 210b.

Then, as shown in FIG. 7A, the polysilicon film 203 is processed to form gate electrodes G. Source/drain diffusion layers S/D are formed in the semiconductor substrate 201 on the two sides of each gate electrode G. In this way, transistors Tr are formed. After that, the conventional techniques are used to form contact plugs 212 in a PMD 211, form metal interconnections 214 and contact plugs 215 in an ILD 213, and form metal interconnections 217 in an ILD 216. In this manner, a semiconductor device is completed.

In the second embodiment described above, as in the first embodiment, the polysilazane film 209 which has good burying properties and is formed by coating is used as a material to be filled in the element isolation trenches 206a and 206b. Accordingly, the STI regions 210a and 210b can be downsized.

Also, in this embodiment, the alumina film 208 is formed between the polysilazane film 209 and silicon nitride film 207. Therefore, a positive fixed electric charge due to the polysilazane film 209 and silicon nitride film 207 can be canceled by a negative fixed electric charge due to the alumina film 208.

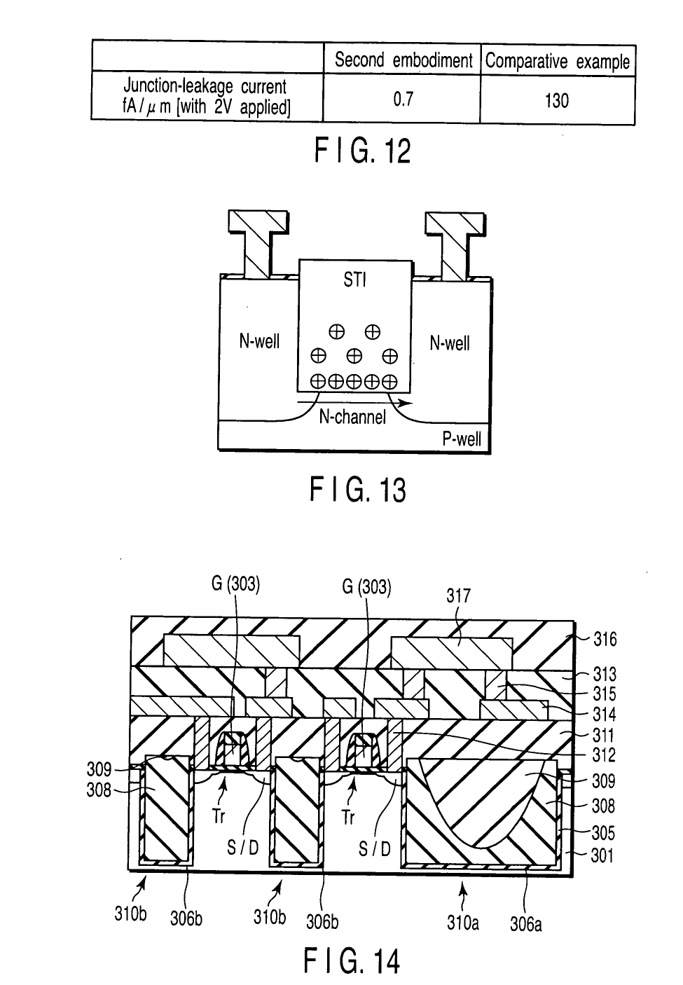

For example, FIG. 12 shows the results of evaluation of N-well-to-N-well junction-leakage currents in the second embodiment of the present invention and in a comparative example. In an element of this comparative example, STI trenches are filled by forming a polysilazane film on a silicon nitride film without forming any alumina film. As shown in FIG. 12, the junction-leakage current of this embodiment is much lower than that of the comparative example. This indicates that the increase in junction-leakage current can be suppressed.

More specifically, in the comparative example, both the silicon nitride film and polysilazane film have a positive fixed electric charge. Therefore, with respect to a P-well on the bottom of the STI, the STI itself in which the silicon nitride film and polysilazane film are filled functions as a gate electrode to which a positive voltage is applied. This forms an N-channel between the N-wells (FIG. 13). By contrast, in this embodiment, the negative fixed electric charge of the alumina film 208 cancels the influence of the positive fixed electric charge of the silicon nitride film 207 and polysilazane film 209. Accordingly, no such problem as in the comparative example arises.

In the second embodiment of the present invention as described above, fine STI regions 210a and 210b of 50 nm or less can be formed while the electrical adverse effects, such as the increase in junction-leakage current, of the polysilazane film 209 are suppressed. Consequently, the performance of the semiconductor device can be further improved by downsizing.

### Third Embodiment

In the third embodiment, as in the second embodiment, a material layer serving as a gate oxide film and gate electrode is preformed on a semiconductor substrate before STI regions are formed. In addition, an HSQ [Hydrogen Silises Quioxane: (HSiO_{3/2})ₙ] film is used as a liner film of a polysilazane film.

FIG. 14 is a sectional view of a semiconductor device according to the third embodiment of the present invention. This semiconductor device according to the third embodiment will be described below.

As shown in FIG. 14, the third embodiment differs from the second embodiment in that an HSQ film 308 obtained by coating is used as a liner film of a polysilazane film 309.

The HSQ film 308 hardly takes in impurity carbon and hence has almost no positive fixed electric charge. On the other hand, the HSQ film 308 is very difficult to process by CMP because its molecular structure is like a basket.

In this embodiment, the polysilazane film 309 and HSQ film 308 are filled in element isolation trenches 306a and 306b in different ways in a wide STI region 310a and in narrow STI regions 310b.

That is, in the wide STI region 310a, the HSQ film 308 having almost no fixed electric charge is buried in the bottom of the element isolation trench 306a in order to avoid fixed electric charge. The opening of the element isolation trench 306a is mostly filled with the polysilazane film 309 which is easy to process by CMP, instead of the HSQ film 308 which is hard to process by CMP.

On the other hand, the narrow STI regions 310b are fine transistor portions sensitive to a fixed electric charge. Therefore, both the bottom and opening of each element isolation trench 306b are almost completely filled with the HSQ film 308 alone. If there is no influence on each transistor Tr, however, the polysilazane film 309 may also slightly exist in that portion of each STI region 310b (near the center of the upper portion of the STI region 310b) that is separated to some extent from the transistor Tr.

Note that in this embodiment, the HSQ film 308 is taken as an example of the insulating film having no fixed electric charge. However, it is also possible to use, e.g., a condensed CVD film made of silane and H₂O₂, in place of the HSQ film 308.

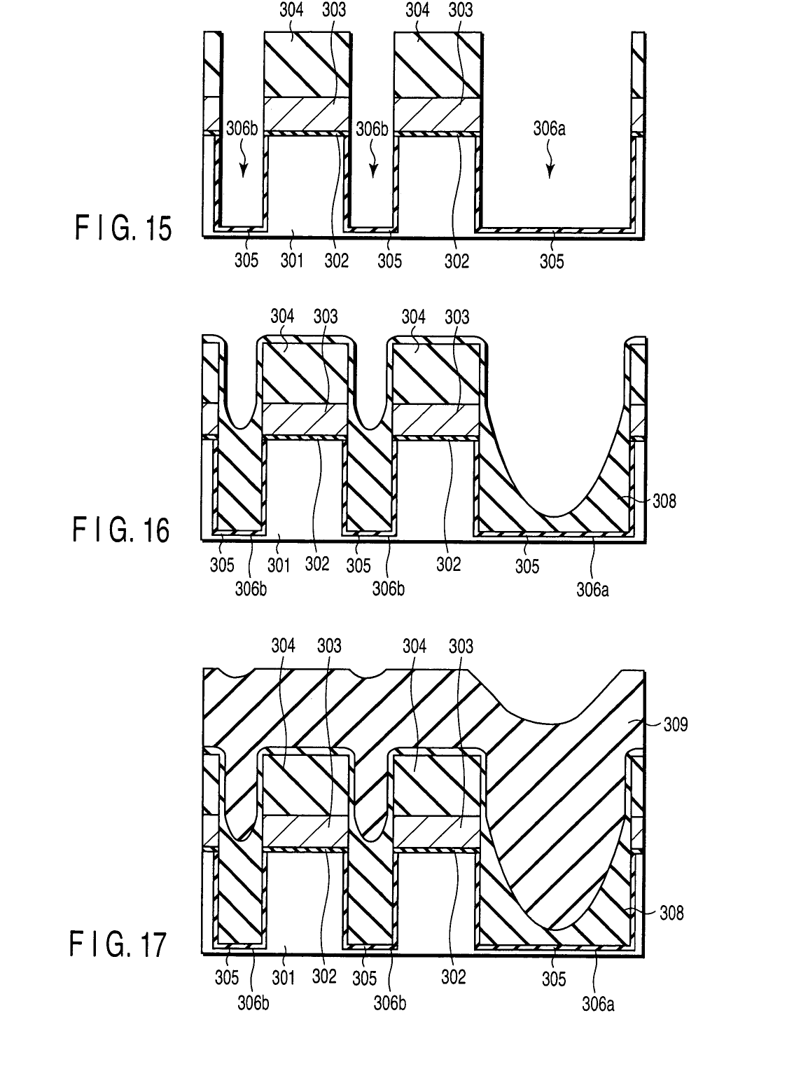

FIGS. 15 to 18 are sectional views showing the fabrication steps of the semiconductor device according to the third embodiment of the present invention. The fabrication method of the semiconductor device according to the third embodiment will be explained below.

First, as shown in FIG. 15, a gate oxide film 302 is formed on a semiconductor substrate 301, and a polysilicon film 303 serving as gate electrodes and having a film thickness of, e.g., 150 nm is formed on the gate oxide film 302. In addition, a silicon nitride film 304 serving as a polishing stopper of CMP and having a film thickness of, e.g., 100 nm is formed on the polysilicon film 303. Then, the well-known lithography technique and RIE technique are used to sequentially process the silicon nitride film 304, polysilicon film 303, gate oxide film 302, and semiconductor substrate 301, thereby forming trenches having an etching depth of, e.g., 200 nm in the semiconductor substrate 301. Subsequently, the inner surfaces of the trenches are thermally oxidized to form a silicon thermal oxide film 305 having a film thickness of, e.g., 4 nm on the side surfaces and bottom surfaces of the trenches. In this manner, element isolation trenches 306a and 306b having an STI structure are formed.

Then, as shown in FIG. 16, an HSQ film 308 having a film thickness of, e.g., 100 nm is formed in the element isolation trenches 306a and 306b and on the silicon nitride film 304. A practical formation method of the HSQ film 308 is as follows.

(a) First, a hydrogen silises quioxane polymer [(HSiO_{3/2})ₙ] solution is prepared by dispersing a hydrogen silises quioxane polymer in MIBK [methylisobutylketone] or the like.

(b) Then, the element isolation trenches 306a and 306b and silicon nitride film 304 are coated with this hydrogen silises quioxane polymer solution by spin coating. The spin coating conditions are that the rotational speed of the semiconductor substrate 301 is 4,000 rpm, the rotation time is 30 sec, the dropping amount of the hydrogen silises quioxane polymer solution is 2 cc, and the target coating film thickness is 100 nm.

(c) An appropriate heat-treatment is then performed to change the film of the hydrogen silises quioxane polymer solution into an HSQ film 308. In this heat-treatment, the semiconductor substrate 301 on which the film is formed is first heated to 150° C. on a hotplate, and then baked in an inert gas ambient for 1 min, thereby evaporating the solvent. After that, the HSQ film 308 is softened as it is baked on the hotplate heated to 200° C. in an inert gas ambient for 1 min. In addition, the HSQ film 308 is fluidized as it is heated on the hotplate at 350° C. on which the residual oxygen partial pressure is controlled to 100 ppm or less. In this way, the HSQ film 308 can be filled even in the narrow element isolation trenches 306a and 306b without any voids.

After being formed by steps (a) to (c) described above, the HSQ film 308 is oxidized in a steam ambient at 350° C. to 450° C., thereby removing hydrogen in the film. This reaction typically progresses as indicated by
HSiO_{3/2}+O→SiO₂+1/2H₂O (2)

Then, as shown in FIG. 17, a polysilazane film 309 having a film thickness of, e.g., 500 nm is formed on the HSQ film 308 by spin coating. The formation method of the polysilazane film 309 is the same as in the first embodiment, so an explanation thereof will be omitted. In this state, the wide element isolation trench 306a is completely filled with the polysilazane 309, but the narrow element isolation trenches 306b are already filled with the HSQ film 308.

The polysilazane film 309 is then heat-treated in a steam ambient at 400° C., thereby removing impurity carbon or hydrocarbon in the film. Furthermore, a heat-treatment is performed in a nitrogen ambient at 800° C. to density the HSQ film 308 and polysilazane film 309.

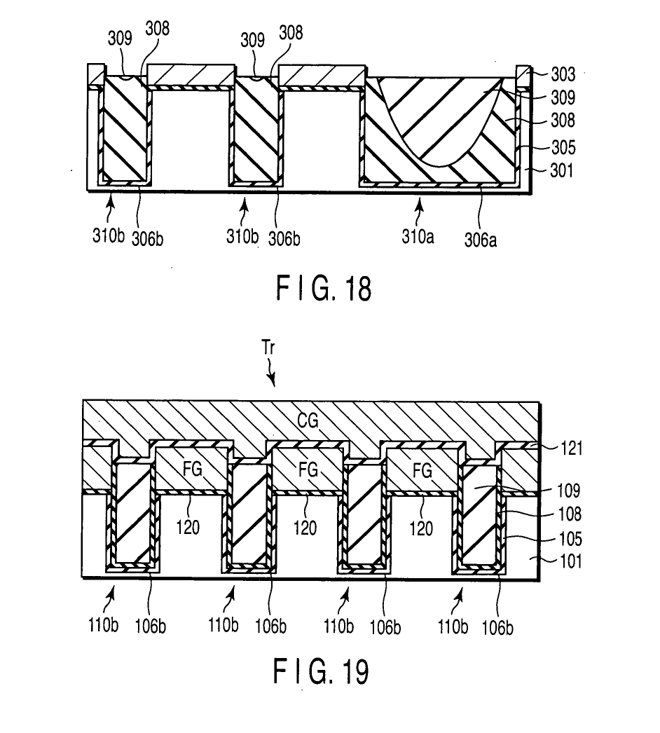

As shown in FIG. 18, the polysilazane film 309 and HSQ film 308 are planarized by CMP. The polysilazane film 309 and HSQ film 308 are then etched back to a desired height by wet etching. After that, the silicon nitride film 304 is removed in hot phosphoric acid to form STI regions 310a and 310b.

Then, as shown in FIG. 14, the polysilicon film 303 is processed to form gate electrodes G. Source/drain diffusion layers S/D are formed in the semiconductor substrate 301 on the two sides of each gate electrode G. In this way, transistors Tr are formed. After that, the conventional techniques are used to form contact plugs 312 in a PMD 311, form metal interconnections 314 and contact plugs 315 in an ILD 313, and form metal interconnections 317 in an ILD 316. In this manner, a semiconductor device is completed.

In the third embodiment described above, as in the first embodiment, the polysilazane film 309 which has good burying properties and is formed by coating is used as a material to be filled in the element isolation trenches 306a and 306b. Accordingly, the STI regions 310a and 310b can be downsized.

Also, as described previously, the positive fixed electric charge of the polysilazane film 309 deteriorates the performance, e.g., shifts the threshold voltage Vth of the transistor Tr, increases the off-leakage current Ioff, and lowers the mobility. However, the HSQ film 308 hardly takes in impurity carbon. Therefore, the transistors Tr can be protected from the influence of the carbon impurity in the polysilazane film 309 by coating the element isolation trenches 306a and 306b with the HSQ film 308 beforehand. Consequently, the problems caused by the fixed electric charge of the polysilazane film 309 can be avoided.

In addition, the polysilazane film 309 is mainly filled in the opening of the wide element isolation region 306a. This advantageously facilitates processing by CMP. On the other hand, the narrow element isolation trenches 306b are fine element portions vulnerable to fixed electric charge. Therefore, the HSQ film 308 having no fixed electric charge is buried in the element isolation trenches 306b. This prevents the problem of fixed electric charge.

Furthermore, it is difficult to increase the thickness of the HSQ film 308 because it has a large film shrinkage amount and hence easily cracks. However, when the HSQ film 308 is formed thin, it is rarely filled in the wide element isolation trench 306a. Therefore, the polysilazane film 309 which seldom cracks can be generated in the element isolation trench 306a.

### Fourth Embodiment

The fourth embodiment is an example in which the STI regions 110a and 110b of the first embodiment are applied to a nonvolatile semiconductor device. Note that it is of course also possible to apply the STI regions 210a, 210b, 310a, and 310b of the second and third embodiments to a nonvolatile semiconductor device.

FIG. 19 is a sectional view of a nonvolatile semiconductor device according to the fourth embodiment of the present invention. This nonvolatile semiconductor device according to the fourth embodiment will be described below.

As shown in FIG. 19, STI regions 110a and 110b are formed in a semiconductor substrate 101. As in the first embodiment, the STI regions 110a and 110b are made of a polysilazane film 109 filled in element isolation trenches 106a and 106b, and a hafnia film 108 formed as an undercoat of the polysilazane film 109.

A tunnel oxide film 120 is formed in element regions isolated by the STI regions 110a and 110b. Floating gate electrodes FG are formed on the tunnel oxide film 120, an inter-electrode insulating film 121 is formed on the floating gate electrodes FG, and a control gate electrode CG is formed on the inter-electrode insulating film 121. In this manner, a nonvolatile memory cell transistor Tr is formed.

In the fourth embodiment described above, as in the first embodiment, the fine STI regions 110a and 110b can be formed while the electrical adverse effects of the polysilazane film 109 are suppressed.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a first element isolation trench formed in a semiconductor substrate and having an STI (Shallow Trench Isolation) structure;
a first insulating film formed in the first element isolation trench and mainly containing a metal oxide; and
a polysilazane film formed on the first insulating film and filled in the first element isolation trench.

2. The device according to claim 1, wherein the first insulating film is one of metal oxides, metal oxynitrides, metal silicates, and metal silicon oxynitrides, and
the metal oxides, metal oxynitrides, metal silicates, and metal silicon oxynitrides each contain at least one of aluminum, hafnium, zirconium, plesiodium, lanthanum, holonium, and erbium.

3. The device according to claim 1, wherein a negative fixed electric charge of the first insulating film cancels a positive fixed electric charge of the polysilazane film.

4. The device according to claim 1, which further comprises a second insulating film formed below the first insulating film in the first element isolation trench, and
in which a negative fixed electric charge of the first insulating film cancels a positive fixed electric charge of the polysilazane film and second insulating film.

5. The device according to claim 1, further comprising:
a tunnel insulating film formed on the semiconductor substrate;
a floating gate electrode formed on the tunnel insulating film;
an inter-electrode insulating film formed on the floating gate electrode; and
a control gate electrode formed on the inter-electrode insulating film.

6. A semiconductor device comprising:
a first element isolation trench formed in a semiconductor substrate and having an STI structure;
a first HSQ film formed in the first element isolation trench; and
a polysilazane film formed on the first HSQ film and filled in the first element isolation trench.

7. The device according to claim 6, wherein the first HSQ film is a coating film.

8. The device according to claim 6, which further comprises:
a second element isolation trench formed in the semiconductor substrate, narrower than the first element isolation trench, and having the STI structure; and
a second HSQ film filled in the second element isolation trench, and
in which the first element isolation trench is filled with the first HSQ film and polysilazane film, and the second element isolation trench is almost filled with the second HSQ film alone.

9. The device according to claim 8, wherein an opening of the first element isolation trench is almost filled with the polysilazane film.

10. A semiconductor device manufacturing method comprising:
forming a first element isolation trench having an STI structure in a semiconductor substrate;
forming a first insulating film mainly containing a metal oxide in the first element isolation trench;
forming a polysilazane film on the first insulating film; and
forming a first STI region by planarizing the first insulating film and polysilazane film.

11. The method according to claim 10, wherein the first insulating film is one of metal oxides, metal oxynitrides, metal silicates, and metal silicon oxynitrides, and
the metal oxides, metal oxynitrides, metal silicates, and metal silicon oxynitrides each contain at least one of aluminum, hafnium, zirconium, plesiodium, lanthanum, holonium, and erbium.

12. The method according to claim 10, wherein the first insulating film is formed by CVD (Chemical Vapor Deposition) or ALD (Atomic Layer Deposition).

13. The method according to claim 10, wherein a negative fixed electric charge of the first insulating film cancels a positive fixed electric charge of the polysilazane film.

14. The method according to claim 10, which further comprises forming a second insulating film below the first insulating film in the first element isolation trench, and
in which a negative fixed electric charge of the first insulating film cancels a positive fixed electric charge of the polysilazane film and second insulating film.

15. The method according to claim 14, wherein the second insulating film is formed by CVD or ALD.

16. The method according to claim 14, further comprising:
forming a gate insulating film and gate material layer in order on the semiconductor substrate before the first element isolation trench is formed; and
forming a gate electrode by processing the gate material layer after the first STI region is formed.

17. A semiconductor device manufacturing method comprising:
forming a first element isolation trench having an STI structure in a semiconductor substrate;
forming a first HSQ film in the first element isolation trench;
forming a polysilazane film on the first HSQ film; and
forming a first STI region by planarizing the first HSQ film and polysilazane film.

18. The method according to claim 17, wherein the first HSQ film is a coating film.

19. The method according to claim 17, which further comprises:
forming, in the semiconductor substrate, a second element isolation trench narrower than the first element isolation trench and having the STI structure; and
forming a second STI region by filling a second HSQ film in the second element isolation trench, and in which the first element isolation trench is filled with the first HSQ film and polysilazane film, and the second element isolation trench is almost filled with the second HSQ film alone.

20. The method according to claim 19, wherein an opening of the first element isolation trench is almost filled with the polysilazane film.
